(19) United States
(12) Patent Application Publication
(10) Pub. No.: US 2015/0372218 A1
(43) Pub. Date: Dec. 24, 2015

(54) PIEZO HAPTIC DRIVER AND METHOD FOR DRIVING THE SAME

(71) Applicant: Samsung Electro-Mechanics Co., Ltd., Suwon-Si (KR)

(72) Inventor: Gyu Won KIM, Suwon-Si (KR)

(73) Assignee: Samsung Electro-Mechanics Co., Ltd., Suwon-Si (KR)

(21) Appl. No.: 14/736,593

(22) Filed: Jun. 11, 2015

(30) Foreign Application Priority Data
Jun. 19, 2014 (KR) 10-2014-0074929

(51) Int. Cl. H01L 41/04; G06F 3/041; H01L 41/09; G06F 3/01

(52) U.S. Cl. CPC H01L 41/042; G06F 3/016; G06F 3/041; H01L 41/09

(57) ABSTRACT

Disclosed herein is a piezo haptic driver capable of preventing a malfunction and being more effectively operated and a method for driving the same. According to an exemplary embodiment of the present disclosure, a piezo haptic driver includes: an analog signal processor driving a piezo element; a controller transferring a control signal controlling the piezo element to the analog signal processor; an interface controller determining a driving of the analog signal processor in response to at least one of an under voltage lock out (UVLO) signal and a thermal shutdown (TSD) signal.

This application claims the benefit under 35 U.S.C. Section 119(a) of Korean Patent Application Serial No. 10-2014-0074929, entitled “Piezo Haptic Driver And Method For Driving The Same” filed on Jun. 19, 2014, which is hereby incorporated by reference in its entirety into this application.

### BACKGROUND

1. Technical Field

The present disclosure relates to a piezo haptic driver and a method for driving the same.

2. Description of Related Art

A touch screen may be designed to be simple and slim while providing a relatively large screen and has recently been applied to a mobile terminal. Unlike a keypad for a general mobile terminal including a plurality of mechanical key buttons, a general touch screen provides soft buttons and therefore does not have a click sense, such that key input errors may frequently occur. To overcome the disadvantages, a haptic method using a piezo element to enable a user to recognize a key input by generating electricity by a pressure generated when a user input device contacts a touch screen has been proposed.

The piezo element described above is driven using a driver. Here, when an input voltage is lower or temperature is high, the driver is likely to be malfunction. Therefore, there is a need to stably operate the driver using a generation signal of under voltage lock out (UVLO) or thermal shutdown (TSD).

### SUMMARY

An object of the present disclosure is to provide a piezo haptic driver capable of preventing a malfunction and being more effectively operated and a method for driving the same.

According to an exemplary embodiment of the present disclosure, there is provided a piezo haptic driver, including: an analog signal processor driving a piezo element; a controller transferring a control signal controlling the piezo element to the analog signal processor; an interface controller determining a driving of the analog signal processor in response to at least one of an under voltage lock out (UVLO) signal and a thermal shutdown (TSD) signal.

According to another exemplary embodiment of the present disclosure, there is provided a method for driving a piezo element: transmitting, by an interface controller, an enable signal so that an amplifier and a boost converter are turned on at different time; sensing at least one of an UVLO signal and a TSD signal and determining the UVLO signal and the TSD signal to be valid when at least one of the UVLO signal and the TSD signal is maintained for a predetermined time; and simultaneously stopping an operation of the amplifier and the boost converter if it is determined that at least one of the UVLO signal and the TSD signal is valid.

### BRIEF DESCRIPTION OF THE DRAWINGS

FIG. 1 is a structural diagram illustrating a piezo haptic driver according to an exemplary embodiment of the present disclosure.

FIG. 2 is a flow chart illustrating an embodiment of an operation of an interface controller illustrated in FIG. 1.

FIG. 3 is a flow chart illustrating another embodiment of an operation of an interface controller illustrated in FIG. 1.

FIG. 4 is a timing diagram illustrating a case in which an UVLO signal or a TSD signal which is valid for the piezo haptic driver illustrated in FIG. 1 is transferred.

FIG. 5 is a timing diagram illustrating the case in which the UVLO signal or the TSD signal which is not valid for the piezo haptic driver illustrated in FIG. 1 is transferred.

### DESCRIPTION

Matters of an action effect and a technical configuration of a piezo haptic driver and a method for driving the same according to an exemplary embodiment of the present disclosure to achieve the above object will be clearly obvious by the following detailed description with reference to the drawings which illustrate exemplary embodiments of the present disclosure.

Further, when it is determined that the detailed description of the known art related to the present disclosure may obscure the gist of the present disclosure, the detailed description thereof will be omitted. In the present specification, the terms first, second, and so on are used to distinguish one element from another element, and the elements are not defined by the above terms.

Exemplary embodiments of the present disclosure will be described in detail with reference to the accompanying drawings illustrating an example of specific exemplary embodiments which may be practiced by the present disclosure. These embodiments will be described in detail for those skilled in the art in order to practice the present disclosure. It should be appreciated that various exemplary embodiments of the present disclosure are different from each other, but do not have to be exclusive. For example, specific shapes, structures, and characteristics described in the present specification may be implemented in another exemplary embodiment without departing from the spirit and the scope of the present disclosure in connection with an exemplary embodiment. In addition, it should be understood that a position or an arrangement of individual components in each disclosed exemplary embodiment may be changed without departing from the spirit and the scope of the present disclosure. Therefore, a detailed description described below should not be construed as being restrictive. In addition, the scope of the present disclosure is defined only by the accompanying claims and their equivalents if appropriate. Similar reference numerals will be used to describe the same or similar functions throughout the accompanying drawings in various aspects.

Hereinafter, embodiments of the present disclosure will be described in detail with reference to the accompanying drawings so that those skilled in the art may easily practice the present disclosure.

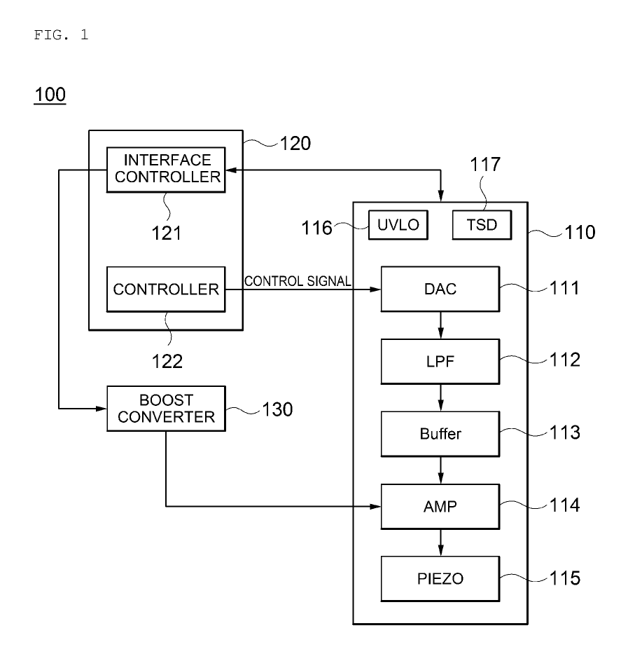

FIG. 1 is a structural diagram illustrating a piezo haptic driver according to an exemplary embodiment of the present disclosure.

Referring to FIG. 1, a piezo haptic driver 100 may include an analog signal processor 110 driving a piezo element 115, a controller 122 transferring a control signal controlling the piezo element 115 to the analog signal processor 110, and an interface controller 121 determining a driving of the analog signal processor 110 in response to at least one of an under voltage lock out (UVLO) signal and a thermal shutdown (TSD) signal. The controller 122 and the interface controller 121 may be included in a single IC 120. An IC 200 may be a digital core.

The analog signal processor 110 may include an amplifier 114 which amplifies a driving signal of a piezo element 150. Further, the analog signal processor 110 may include a DAC 111 converting a digital signal into an analog signal, a low pass filter 112 removing noise of a signal output from the DAC 111, and a buffer 113 buffering a signal output from the low pass filter 112. The amplifier 114 may receive and amplify a signal buffered by the buffer 113. Further, the analog signal processor 110 may include the piezo element 115 which is driven by the signal amplified by the amplifier 114. However, a configuration of the analog signal processor 110 is not limited thereto and the piezo element 115 may be positioned outside the analog signal processor 110 to receive a driving signal from the analog signal processor 110. The piezo element 115 may generate electricity by a generated pressure and may generate electricity by a pressure generated due to a touch by a finger, etc., or a pressure generated due to a warpage of the element. The amplifier 114 which amplifies the driving signal and transfers the amplified driving signal to the piezo element 115 may be driven by a driving voltage. A boost converter 130 which outputs the driving voltage may be present in the driver 100. However, the boost converter 130 is not limited thereto but the boost converter 130 may be positioned outside the driver 100. Further, the analog signal processor 110 may include an UVLO circuit 116 which generates an UVLO signal and a TSD circuit 117 which generates a TSD signal. The UVLO signal may be generated when a sensed input voltage is equal to or less than a predetermined level and the TSD signal may be generated when the sensed temperature is equal to or more than a predetermined temperature. That is, the driver 100 may be prevented from being damaged due to a low input voltage or a high temperature by using the UVLO signal and the TSD signal.

The controller 122 generates the control signal which controls the piezo element 115 and transfers the generated control signal to the analog signal processor 110 and thus the piezo element 115 may be driven by the controller 122. The control signal output from the controller 122 may be a digital signal and is transferred to the DAC 111 of the analog signal processor 110 and thus may be converted into an analog signal. Further, the controller 122 may be connected to the boost converter 130 which outputs a driving voltage driving the amplifier 114. Here, a converter which outputs the driving voltage driving the amplifier 114 is described as the boost converter but is not limited thereto and therefore various converters such as a buck converter, a flyback converter, and an LLC may be applied.

The interface controller 121 may determine the driving of the analog signal processor 110. In other words, the interface controller 121 may transfer or block an enable signal so that the DAC 111, the low pass filter 112, the buffer 113, and the amplifier 114 which are included in the analog signal processor 110 are each turned on or off to drive each component of the analog signal processor 110 or stop the driving thereof. Further, the interface controller 121 may receive at least one of the UVLO signal and the TSD signal to determine the driving of the analog signal processor 110. That is, when the input voltage is lower than a reference voltage and/or the temperature is higher than a reference temperature, the interface controller 121 may stop the operation of the piezo haptic driver 100. Herein, it is described that the UVLO circuit 116 and the TSD circuit 117 are included in the analog signal processor 110, but they are not limited thereto. Therefore, the UVLO circuit 116 and the TSD circuit 117 may be installed in an external apparatus (not illustrated) and the interface controller 121 may be operated by receiving the UVLO signal and the TSD signal from the external apparatus.

According to the exemplary embodiment of the present disclosure, when the received UVLO signal or TSD signal does not maintain a preset time, the interface controller 121 may drive the analog signal processor 110 and when the received UVLO signal or TSD signal maintains a preset time, the interface controller 121 may stop the operation of the analog signal processor 110. Further, when the received UVLO signal or TSD signal maintains the preset time, the interface controller 121 may stop the driving of the amplifier 114 and the boost converter 130. Further, the interface controller 121 may perform a control to make a driving timing of at least one of the TSD circuit 117, the UVLO circuit 116, the DAC 111, the amplifier 114, and the boost converter 130 different. That is, the interface controller 121 may transfer or block the enable signal to or from each of the TSD circuit 117, the UVLO circuit 116, the DAC 111, the amplifier 114, and the boost converter 130 to turn on or off them and the interface controller 121 may make the applying timing of the enable signal different and thus may make the driving timing different. Further, the interface controller 121 may simultaneously stop the driving of the TSD circuit 117, the UVLO circuit 116, the DAC 111, the amplifier 114, and the boost converter 130. Here, the simultaneous stopping of the driving does not mean that the driving stops in complete accord with time but may include that the driving stops at a slight time difference.

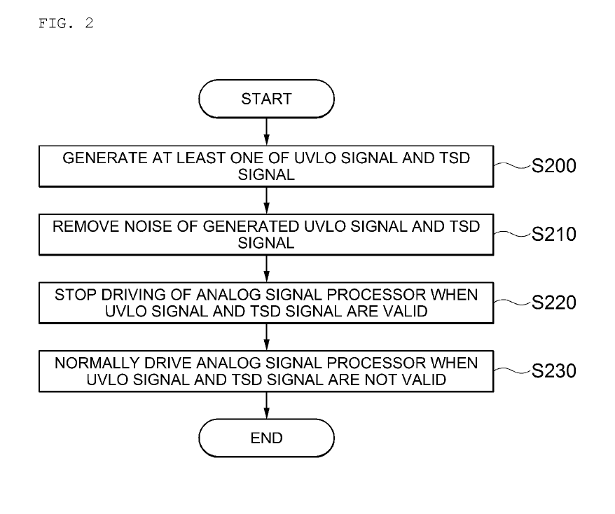

FIG. 2 is a flow chart illustrating an embodiment of the operation of the interface controller illustrated in FIG. 1.

Referring to FIG. 2, the interface controller 121 may determine whether at least one of the UVLO signal and the TSD signal is generated (S200). When the UVLO circuit 116 or the TSD circuit 117 is included in the analog signal processor 110, the interface controller 121 may receive the UVLO signal and the TSD signal from the analog signal processor 110 and when the UVLO circuit 116 or the TSD circuit 117 is included in the external apparatus (not illustrated) (for example, external host apparatus), the interface controller 121 may receive the UVLO signal and the TSD signal from the external apparatus. The interface controller 121 may determine whether the TSD circuit 117 or the UVLO circuit 116 generates at least one of the UVLO signal and the TSD signal to determine whether at least one of the UVLO signal and the TSD signal is generated. The interface controller 121 may remove noises of the generated UVLO signal and TSD signal (S210). The interface controller 121 determines the UVLO signal and the TSD signal as a valid signal only when the generated UVLO signal and the TSD signal are maintained to be longer than a preset time, thereby removing the noises.

When the UVLO signal or the TSD signal is valid, the interface controller 121 may stop the driving of the analog signal processor 110 (S220). That is, when the generated UVLO signal and/or TSD signal is maintained to be longer than the preset time, the interface controller 121 may determine that the UVLO signal and/or the TSD signal is validly generated to stop the driving of the analog signal processor 110.

Further, when the UVLO signal and/or the TSD signal is invalid, the interface controller 121 does not stop the driving of the analog signal processor 110 but may continuously normally drive the analog signal processor 110 (S230). That is, when the generated UVLO signal or TSD signal is maintained to be shorter than the preset time, the interface controller 121 determines the UVLO signal and/or the TSD signal as noise and thus performs processing to prevent the UVLO signal or the TSD signal from being generated so as to normally drive the analog signal processor. In this case, when the UVLO signal and/or the TSD signal is not generated or the invalid UVLO signal and/or TSD signal is generated after a predetermined time lapses after the valid UVLO signal and/or the TSD signal is generated, the analog signal processor 110 may be normally driven again. As such, when the analog signal processor 110 is driven again, each component of the analog signal processor 110 may start to be driven again in a first driven order.

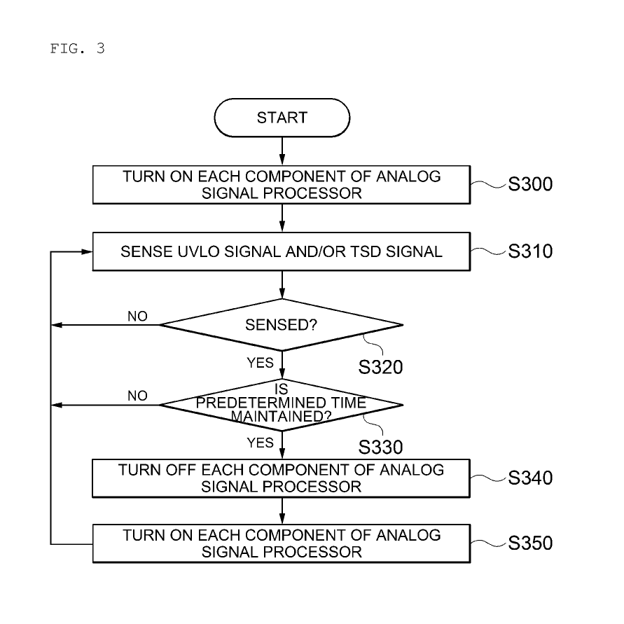

FIG. 3 is a flow chart illustrating another embodiment of the operation of the interface controller illustrated in FIG. 1.

Referring to FIG. 3, each component of the analog signal processor 110 is turned on (S300). Each component of the analog signal processor 110 illustrated in FIG. 1 receives the enable signal from the interface controller 121 and thus may be turned on. Further, the interface controller 121 senses whether the UVLO signal and/or the TSD signal is generated (S310). In this case, the interface controller 121 may periodically sense the UVLO signal and/or the TSD signal. Further, when the UVLO signal and/or the TSD signal is sensed, the interface controller 121 determines whether the sensed UVLO signal and/or the TSD signal maintains the preset time (S320). If it is determined that the sensed UVLO signal and/or TSD signal does not maintain the preset time, the interface controller 121 continuously turns on each component of the analog signal processor 110. Further, it is determined whether the sensed UVLO signal and/or the TSD signal maintains the preset time (S330). If it is determined that the sensed UVLO signal and/or TSD signal maintains the preset time, the interface controller 121 blocks the enable signal from being transferred to each component of the analog signal processor 110 to stop the driving of the analog signal processor. Further, if it is determined that the sensed UVLO signal and/or TSD signal does not maintain the preset time, the interface controller 121 may determine the sensed UVLO signal and/or TSD signal as noise to continuously operate the analog signal processor 110. In this case, the interface controller 121 blocks the enable signal from being transferred to each component of the analog signal processor 110 and thus may be in a turn off state. In this case, the interface controller 121 may simultaneously turn off each component of the analog signal processor 110. Further, the interface controller 121 may transfer a turn on signal to each component of the analog signal processor 110 after the predetermined time lapses after the analog signal processor 110 is in a turn off state (S350). In this case, each component of the analog signal processor 110 may be configured to receive the enable signal to the order that each component of the analog signal processor 110 is in a turn on state in an early stage.

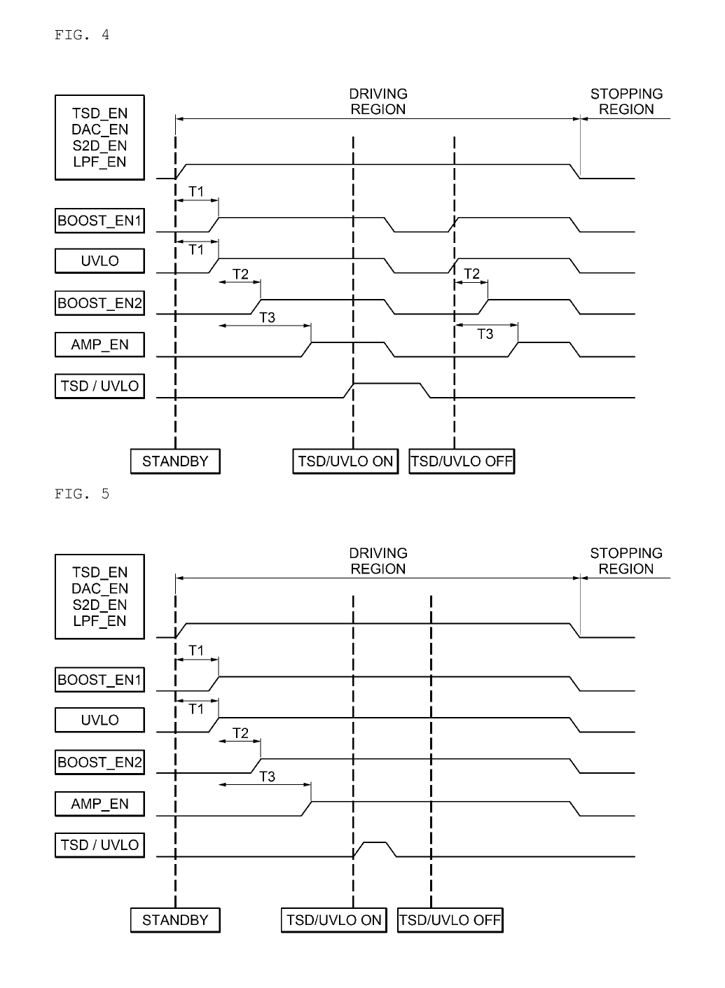

FIG. 4 is a timing diagram illustrating a case in which an UVLO signal or a TSD signal which is valid for the piezo haptic driver illustrated in FIG. 1 is transferred and FIG. 5 is a timing diagram illustrating the case in which the UVLO signal or the TSD signal which is not valid for the piezo haptic driver illustrated in FIG. 1 is transferred.

Referring to FIGS. 4 and 5, first, the interface controller 121 may perform a control to make the driving timing of at least one of the TSD circuit, the UVLO circuit 116, the DAC 111, the amplifier 114, and the boost converter 130 different. Further, the interface controller 121 may transfer the enable signal to the TSD circuit 117, the DAC 111, the buffer 113, and the low pass filter 112 in a high state at a first driving start point where it enters a standby state to turn on the TSD circuit 117, the DAC 111, the buffer 113, and the low pass filter 112 of the analog signal processor 110, respectively. Further, the interface controller 121 may transfer an enable signal to the boost converter 130 and the UVLO circuit 116 in a high state at the time of a second driving timing when a first time T1 lapses to turn on the boost converter 130 and the UVLO circuit 116. In this case, the boost converter 130 starts an initial driving and thus the boost converter 130 does not reach a normal driving state. Further, after the boost converter 130 and the UVLO circuit 116 are turned on, the interface controller 121 transfers an enable signal to the boost converter 130 in a high state at a fourth driving timing when a second time T2 lapses to enable the boost converter 130 to be normally operated. Further, in the above state, when the TSD signal and/or the UVLO signal is input to or generated in the analog signal processor 110, the interface controller 121 determines whether the generated TSD signal and/or UVLO signal is maintained for the predetermined time. When periodically sensing the TSD signal and/or the UVLO signal, it is determined whether the TSD signal and/or the UVLO signal is sensed even in a next found period and thus determines whether the TSD signal and/or the UVLO signal is maintained for the predetermined time. Further, as illustrated in FIG. 4, if it is determined that the TSD signal and/or the UVLO signal is maintained for the predetermined time, the interface controller 121 may determine that the TSD signal and/or UVLO signal is normally generated to turn off the analog signal processor 110. To be continued, the interface controller 121 determines whether the TSD signal and/or the UVLO signal is generated. That is, the interface controller 121 may determine whether the TSD signal and/or the UVLO signal is generated in a next period. Further, if it is determined that the TSD signal and/or the UVLO signal is no more generated, the interface controller 121 does not directly turn on the analog signal processor 110 but may determine whether the TSD signal and/or the UVLO signal is not generated even after the predetermined time lapses. That is, the interface controller 121 may determine whether the TSD signal and/or the UVLO signal is generated in a next period to determine whether the predetermined time lapses. If it is determined that the TSD signal and/or the UVLO signal is not generated even after the predetermined time lapses, the interface controller 121 may turn on the analog signal processor 110. In this case, the interface controller 121 may turn on each component of the analog signal processor 110 in the same order as when each component of the analog signal processor 110 is first turned on. Further, the interface controller 121 may identically control the driving ending timing of at least one of the TSD circuit 117, the UVLO circuit 116, the DAC 111, and the amplifier 114. Further, when the interface controller 121 does not directly turn on each component of the analog signal processor 110, it is possible to prevent a wrong signal from being transferred to the piezo haptic driver 100 due to noise or malfunction.

On the other hand, as illustrated in FIG. 5, when the TSD signal and/or UVLO signal input to the analog signal processor 110 is generated and then is not maintained for the predetermined time, the interface controller 121 may determine the TSD signal and/or the UVLO signal as noise, not as a normal signal.

According to the piezo haptic driver and the method for driving the same in accordance with the exemplary embodiments of the present disclosure, it is possible to prevent the driver from being malfunctioned, damaged, and the like by making the UVLO signal and the TSD signal stop the driver. Further, it is possible to block noise and increase reliability.

In claims in the present specification, elements represented as a means for performing a specific function include any scheme performing the specific functions and the elements may include a combination of circuit elements performing the specific function or software in any form including firmware, microcode, and the like which are coupled with a circuit suitable to perform software for performing the specific function.

In the present specification, ‘one embodiment’ of principles of the present disclosure and names for various changes of the expression mean that specific features, structures, characteristics, and the like, associated with the embodiment are included in at least one embodiment of the principle of the present disclosure. Therefore, the expression ‘one embodiment’ and any other modification examples disclosed throughout the present specification do not necessarily mean the same embodiment.

In the present specification, ‘connected’ or ‘connecting’ and names for various modifications of these expressions are used as a meaning including ones directly connected to other components or ones indirectly connected thereto through other components. Unless explicitly described to the contrary, a singular form includes a plural form in the present specification. In addition, components, steps, operations, and elements mentioned as ‘comprise’ or ‘comprising’ in the present specification do not exclude the existence or addition of one or more other components, steps, operations, and elements, and apparatuses.

What is claimed is:

1. A piezo haptic driver, comprising:
an analog signal processor driving a piezo element;
a controller transferring a control signal controlling the piezo element to the analog signal processor;
an interface controller determining a driving of the analog signal processor in response to at least one of an under voltage lock out (UVLO) signal and a thermal shutdown (TSD) signal.

2. The piezo haptic driver according to claim 1, wherein the analog signal processor includes an amplifier which amplifies a driving signal of the piezo element.

3. The piezo haptic driver according to claim 2, wherein the interface controller is connected to a boost converter which outputs a driving voltage driving the amplifier.

4. The piezo haptic driver according to claim 1, wherein when the UVLO signal or TSD signal does not maintain a preset time, the interface controller drives the analog signal processor and when the UVLO signal or the TSD signal maintains a preset time, the interface controller stops an operation of the analog signal processor.

5. The piezo haptic driver according to claim 4, wherein when the UVLO signal or the TSD signal maintains the preset time, the interface controller stops a driving of an amplifier and a boost converter.

6. The piezo haptic driver according to claim 4, wherein the analog signal processor includes at least one of an UVLO circuit and a TSD circuit.

7. The piezo haptic driver according to claim 6, wherein the analog signal processor further includes a DAC which converts the control signal into an analog signal.

8. The piezo haptic driver according to claim 7, wherein the interface controller performs a control to make a driving timing of at least one of the TSD circuit, the UVLO circuit, the DAC, an amplifier, and a boost converter different.

9. The piezo haptic driver according to claim 8, wherein the interface controller starts to drive the TSD circuit and the DAC at a first driving timing, starts to initially drive the amplifier and drive the UVLO circuit at a second driving timing, and starts to normally drive the amplifier at a third driving timing.

10. The piezo haptic driver according to claim 8, wherein the interface controller performs a control to make a driving ending timing of the TSD circuit, the UVLO circuit, the DAC, and the amplifier identical.

11. A method for driving a piezo element using an analog signal processor at least including an amplifier which outputs a control signal controlling the piezo element and a boost converter which transfers a driving voltage of the amplifier, the method comprising:
transmitting, by an interface controller, an enable signal so that the amplifier and the boost converter are turned on at different time;
sensing at least one of an UVLO signal and a TSD signal and determining the UVLO signal and the TSD signal to be valid when at least one of the UVLO signal and the TSD signal is maintained for a predetermined time or more; and
simultaneously stopping an operation of the amplifier and the boost converter if it is determined that at least one of the UVLO signal and the TSD signal is valid.

12. The method according to claim 11, wherein in the transmitting, by the interface controller, the enable signal so that the amplifier and the boost converter are turned on at different time, the boost converter is turned on and then the amplifier is turned on.

13. The method according to claim 11, wherein the analog signal processor further includes a DAC, a low pass filter, and a buffer, the interface controller outputs the enable signal to simultaneously turn on the DAC, the low pass filter, and the buffer and then outputs the enable signal to turn on the boost converter.

14. The method according to claim 11, further comprising:
when the UVLO signal and the TSD signal are not generated for a predetermined time, again driving the analog signal processor.
